(19) United States
(12) Patent Application Publication
(10) Pub. No.: US 2024/0321748 A1
(43) Pub. Date: Sep. 26, 2024

(54) IRREGULAR-SHAPED POWER RAIL IN CELL POWER DISTRIBUTION

(71) Applicant: International Business Machines Corporation, Armonk, NY (US)

(72) Inventors: Lawrence A. Clevenger, Saratoga Springs, NY (US); Albert M. Chu, Nashua, NH (US); Geng Han, Niskayuna, NY (US); Brent A. Anderson, Jericho, VT (US); Ruilong Xie, Niskayuna, NY (US); Carl Radens, LaGrangeville, NY (US); Ravikumar Ramachandran, Pleasantville, NY (US); Mahender Kumar, Clifton Park, NY (US)

(21) Appl. No.: 18/188,736

(22) Filed: Mar. 23, 2023

(51) Int. Cl. H01L 23/528

(52) U.S. Cl. CPC H01L 23/5286; H01L 23/5283

(57) ABSTRACT

A semiconductor structure is presented including a power rail having a non-rectangular shape and a middle-of-line (MOL) contact layer electrically connected to the power rail by a metal wiring layer. The non-rectangular shape of the power rail defines at least one notch. Alternatively, the non-rectangular shape of the power rail defines at least one extension. The power rail can be a via rail or a VARAIL.

### BACKGROUND

The present invention relates generally to semiconductor devices, and more specifically, to constructing an irregular-shaped power rail in cell power distribution.

Semiconductor devices are used in a variety of electronic applications, such as personal computers, cell phones, digital cameras, and other electronic equipment. Semiconductor devices are usually fabricated by sequentially depositing insulating or dielectric layers, conductive layers, and semiconductive layers of material over a semiconductor substrate, and patterning the various material layers using lithography to form circuit components and elements thereon.

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node. With the increased demands for miniaturization, higher speed, greater bandwidth, lower power consumption, and lower latency, chip layout has become more complicated and difficult to achieve in the production of semiconductor dies.

### SUMMARY

In accordance with an embodiment, a semiconductor structure is provided. The semiconductor structure includes a power rail having a non-rectangular shape and a middle-of-line (MOL) contact layer electrically connected to the power rail by a metal wiring layer.

In accordance with another embodiment, a semiconductor structure is provided. The semiconductor structure includes an irregular-shaped power rail and a middle-of-line (MOL) contact layer electrically connected to the irregular-shaped power rail by a metal wiring layer.

In accordance with yet another embodiment, a method is provided. The method includes forming a power rail having a non-rectangular shape and electrically connecting a middle-of-line (MOL) contact layer to the power rail by a metal wiring layer.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a top view of a power rail having a conventional rectangular shape and a power rail having an irregular-shape with extensions, in accordance with an embodiment of the present invention;

FIG. 2 is a top view of a power rail having a conventional rectangular shape and a power rail having an irregular-shape with a notch, in accordance with an embodiment of the present invention;

FIG. 3 is a top view of a power rail having a conventional rectangular shape and a power rail having an irregular-shape with two notches, in accordance with an embodiment of the present invention;

FIG. 4 is a top view of a layout depicting an irregular-shaped power rail with a plurality of notches (and or extensions), in accordance with an embodiment of the present invention; and

FIG. 5 is a top view of a power rail having a conventional rectangular shape and a power rail having an irregular-shape with extensions, as well as cross-sectional views of the power rails, in accordance with an embodiment of the present invention.

Throughout the drawings, same or similar reference numerals represent the same or similar elements.

### DETAILED DESCRIPTION

Embodiments in accordance with the present invention provide methods and devices for constructing an irregular-shaped power rail in cell power distribution. As a height of a logic cell is reduced, the power rail design arc may become a limiting factor. As such, conventional rectangular-shaped power rails may adversely affect area scaling and circuit performance.

Fin-based active devices, primarily transistors, are extensively applied for the production of standard cells and other active device configurations processed in the front-end-of-line (FEOL) part of the integrated circuit fabrication process, and include finFETs, as well as more recent devices based on nano-wires or nano-sheets. An example technology involves the use of buried interconnect rails in the FEOL. Buried power rails (BPRs) can directly connect the transistors in the FEOL to a power delivery network located entirely on the back side of an integrated circuit chip. In particular, the source or drain area of a number of transistors are directly connected to a buried rail. The current practice for realizing this configuration is to produce an interconnect via to the buried rail, and to couple the interconnect via to the source or drain area through a local interconnect that is part of the source/drain contact level of the chip, also referred to as the “middle end of line,” which is a transition between the active devices in the FEOL, and the interconnect levels (M1, M2, etc.,) in the back-end-of-line (BEOL).

Some implementations of this approach have a number of drawbacks. As the rails are buried underneath the active devices, the size of the buried power rail (BPR) is limited by the cell-to-cell space between two nearby active regions. As cell height scales down, so does the cell-to-cell space, the buried power rail size decreases, and its resistance increases, which can potentially degrade circuit performance.

Embodiments in accordance with the present invention alleviate such spacing issues by providing a method and structure of forming an irregular-shaped power rail in cell power distribution that can increase power rail to power contact (CA) space for the signal CA and increase power rail to CA overlap for a power CA. The irregular-shape of the power rail can be non-linear or can include one or notches or one or more extensions or projections, or a combination thereof. The notches or projections can be aligned with the signal CA or the power CA, thus resulting in a very short cell height to improve area scaling and circuit performance.

Examples of semiconductor materials that can be used in forming such structures include silicon (Si), germanium (Ge), silicon germanium alloys (SiGe), silicon carbide (SiC), silicon germanium carbide (SiGeC), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

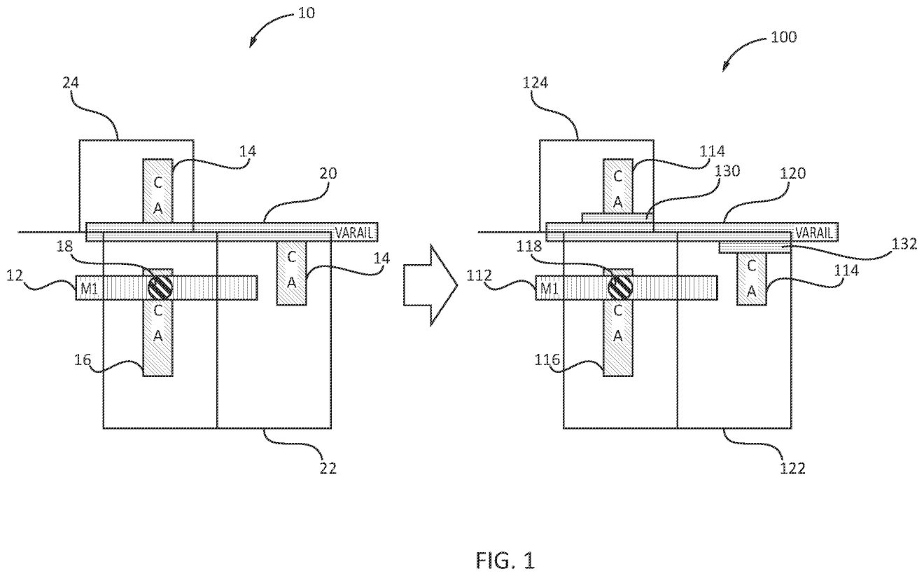

FIG. 1 is a top view of a power rail having a conventional rectangular shape and a power rail having an irregular-shape with extensions, in accordance with an embodiment of the present invention.

Structure 10 depicts conventional embedded frontside to backside signal vias in an edge cell. In the structure 10, a power rail 20 is shown having a rectangular shape. A metal line 12 (M1) is shown parallel to the power rail 20. The metal line 12 (M1) represents a first level of interconnect wiring and can be referred to as a metal wiring layer.

Two power contact layers (CA) 14 and a signal contact layer (CA) 16 are shown in relation to the power rail 20. The power rail 20 is disposed over a portion of each of the power CAs 14. The power CAs 14 are positioned perpendicular to the power rail 20. Therefore, there is a partial overlap between the power CAs 14 and the power rail 20.

The signal CA 16 is positioned perpendicular to the metal line 12. The signal CA 16 is vertically aligned with at least one of the power CAs 14. A via 18 electrically connects the metal line 12 to the signal CA 16. The signal CA 16 does not overlap with the power rail 20.

In one instance, the power rail 20 can be a via rail. In another instance, the power rail 20 can be a VARAIL. VARAIL is defined as a VABAR used for power rail connections. VABAR is defined as a via layer (VA) in the shape of a BAR (i.e., not square).

Electrical connections 22, 24 to the power rail 20 are also shown.

In the structure 100, a power rail 120 is shown having a non-rectangular shape. The non-rectangular shape can be referred to as a nonlinear shape or irregular-shape or stepped configuration. Irregular-shaped refers to an unbalanced or non-normal or non-conventional or asymmetrical shape and/or arrangement. Irregular-shaped can also refer to uneven or unequal portions or sections.

The nonrectangular power rail 120 can include a first projection 130 and a second projection 132. The first projection 130 and the second projection 132 can also be referred to as extensions. The first projection 130 extends over more surface area of the CA contact or power CA 114 (left-hand side) and the second projection 132 extends over more surface area of the CA contact or power CA 114 (right-hand side). Therefore, more surface area of the power rail 120 overlaps with both the power contacts 114 (due to the outward sections). The first and second projections 130, 132 thus enable an increase in VARAIL to CA overlap for power CAs 114.

A width of the first projection 130 is greater than a width of the power contact 114 (left-hand side) and a width of the second projection 132 is greater than a width of the CA contact (right-hand side). Thus, the non-rectangular power rail 120 has two stepped portions, the first stepped portion extending over or overlapping a portion of the first power contact 114 and the second stepped portion extending over or overlapping a portion of the second power contact 114.

A metal line 112 (M1) is shown parallel to the non-rectangular power rail 120. The metal line 112 (M1) represents a first level of interconnect wiring and can be referred to as a metal wiring layer.

Two power contacts (CA) 114 and a signal contact (CA) 116 are shown in relation to the non-rectangular power rail 120. The non-rectangular power rail 120 is disposed over a portion of each of the power CAs 114. The power CAs 114 are positioned perpendicular to the non-rectangular power rail 120. Therefore, there is a partial overlap between the power CAs 114 and the non-rectangular power rail 120. In fact, the overlap is greater in the structure 100 because of the first projection 130 and the second projection 132 (outward extensions). In other words, the VARAIL to power CA overlap is greater because of the first projection 130 and the second projection 132.

The signal CA 116 is positioned perpendicular to the metal line 112. The signal CA 116 is vertically aligned with at least one of the power CAs 114. A via 118 electrically connects the metal line 112 to the signal CA 116. The signal CA 116 does not overlap with the non-rectangular power rail 120. The width of the power rail 120 is wider in the region connecting to the power CAs 114. Stated differently, the width of the power rail 120 is narrower in the region not connecting to the power CAs 114.

In one instance, the power rail 120 can be a via rail. In another instance, the non-rectangular power rail 120 can be a VARAIL. VARAIL is defined as a VABAR used for power rail connections. VABAR is defined as a via layer (VA) in the shape of a BAR (i.e., not square).

Electrical connections 122, 124 to the non-rectangular power rail 120 are also shown.

One skilled in the art can incorporate a plurality of projections of different widths across the length of the power rail 120.

Non-limiting examples of suitable conductive materials for the first level of interconnect wiring include a refractory metal liner such as TaN, an adhesion metal liner, such as Co or Ru, and a conductive metal fill, such as Al, W, Cu, Co, Ru, Mo, Ir, etc. The conductive material can further include dopants that are incorporated during or after deposition. The conductive metal can be deposited by a suitable deposition process, for example, CVD, PECVD, PVD, plating, thermal or e-beam evaporation, and sputtering. The only requirement for the metal layer is to have enough etch selectivity against other metal layers in the order of greater than 10:1.

Regarding various dielectrics or dielectric layers discussed herein, the dielectrics can include, but are not limited to, SiN, SiOCN, SiOC, SiC, SION, SiBCN, SO₂, or ultra-low-k (ULK) materials, such as, for example, porous silicates, carbon doped oxides, silicon dioxides, silicon nitrides, silicon oxynitrides, carbon-doped silicon oxide (SiCOH) and porous variants thereof, silsesquioxanes, siloxanes, or other dielectric materials having, for example, a dielectric constant in the range of about 2 to about 10.

In some embodiments, the dielectrics can be conformally deposited using atomic layer deposition (ALD) or, chemical vapor deposition (CVD). Variations of CVD processes suitable for forming the dielectrics include, but are not limited to, Atmospheric Pressure CVD (APCVD), Low Pressure CVD (LPCVD) and Plasma Enhanced CVD (PECVD), Metal-Organic CVD (MOCVD) and combinations thereof can also be employed.

The etching can include a dry etching process such as, for example, wet etch, reactive ion etching, plasma etching, ion etching or laser ablation. The etching can further include a wet chemical etching process in which one or more chemical etchants are used to remove portions of the blanket layers that are not protected by the patterned photoresist.

The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process. Ruthenium metal is generally etched using O₂ with Ar for the physical component and CH₄ as a dilution gas to reduce the polymerization. Other dry etchant gasses can include, chlorine base gases (e.g., Cl₂, BCl₃), Tetrafluoromethane (CF₄), nitrogen trifluoride (NF₃), sulfur hexafluoride (SF₆), and helium (He), and Chlorine trifluoride (ClF₃). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF₄), and gas mixture with hydrogen (H₂). Chemical vapor etching can be performed by CVD with suitable pressure and temperature.

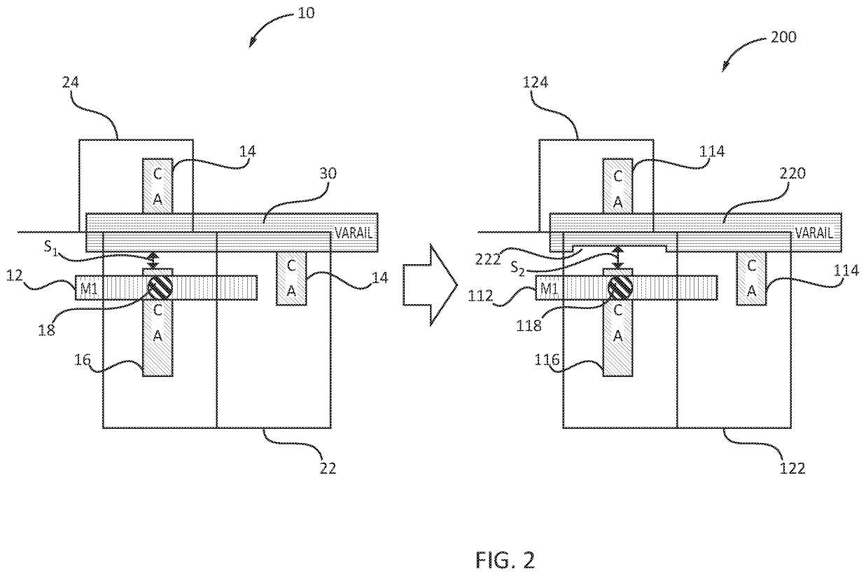

FIG. 2 is a top view of a power rail having a conventional rectangular shape and a power rail having an irregular-shape with a notch, in accordance with an embodiment of the present invention.

Similar to FIG. 1, in the structure 10, the power rail 30 is shown having a rectangular shape. The power rail 30 of FIG. 2 is thicker than the power rail 20 of FIG. 1.

The VARAIL to signal CA space S₁ is shown.

Similar to FIG. 1, in the structure 200, the power rail 220 is shown having a non-rectangular shape. In fact, the power rail 220 defines a notch 222. The notch 222 can also be referred to as a recess or cavity or depression or indentation. The notch 222 creates a VARAIL to signal CA space S2 as shown. S2 is greater than S₁. Thus, the VARAIL to signal CA space is increased by the formation of the notch 222. The width of the notch 222 is greater than a width of the signal CA 116. The width of the power rail 220 is narrower in the region adjacent to a non-connecting CA. Stated differently, the width of the power rail 220 is wider in the region not adjacent to a non-connecting CA.

One skilled in the art can incorporate a plurality of notches of different widths across the length of the power rail 220.

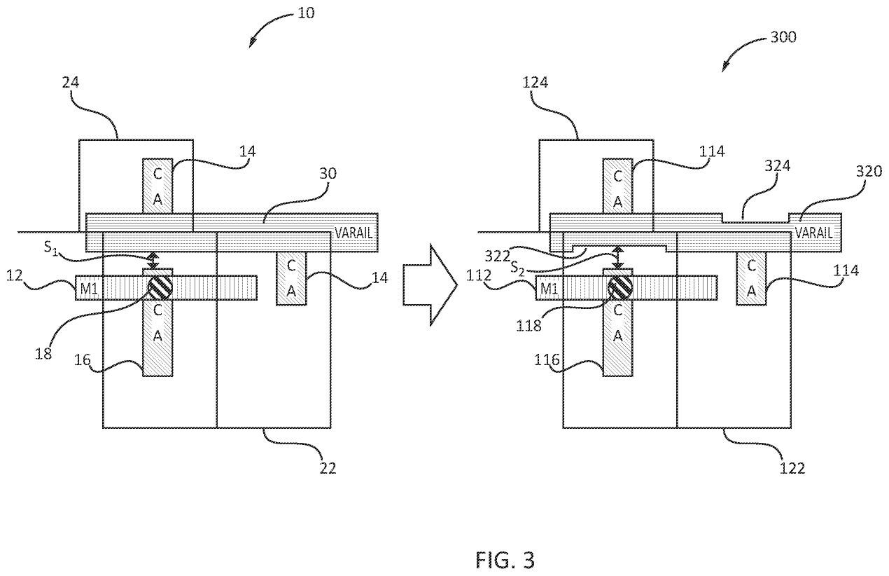

FIG. 3 is a top view of a power rail having a conventional rectangular shape and a power rail having an irregular-shape with two notches, in accordance with an embodiment of the present invention.

Similar to FIG. 1, in the structure 10, the power rail 30 is shown having a rectangular shape. The power rail 30 of FIG. 2 is thicker than the power rail 20 of FIG. 1.

The VARAIL to signal CA space S₁ is shown.

Similar to FIG. 1, in the structure 300, the power rail 320 is shown having a non-rectangular shape. In fact, the power rail 320 defines a first notch 322 and a second notch 324. The first notch 322 and the second notch 324 can be referred to as recesses or cavities or depressions or indentations. The first notch 322 creates a VARAIL to signal CA space S2 as shown. S2 is greater than S₁. Thus, the VARAIL to signal CA space is increased by the formation of the notch 322. The second notch 324 can also increase VARAIL to signal CA space of other signal CAs (not shown). The width of the notch 322 is greater than a width of the signal CA 116. The width of the power rail 320 is narrower in the region adjacent to a non-connecting CA. Stated differently, the width of the power rail 320 is wider in the region not adjacent to a non-connecting CA.

One skilled in the art can incorporate a plurality of notches of different widths across the length of the power rail 320, and on both sides of the power rail 320 based on the location of neighboring power CAs 114.

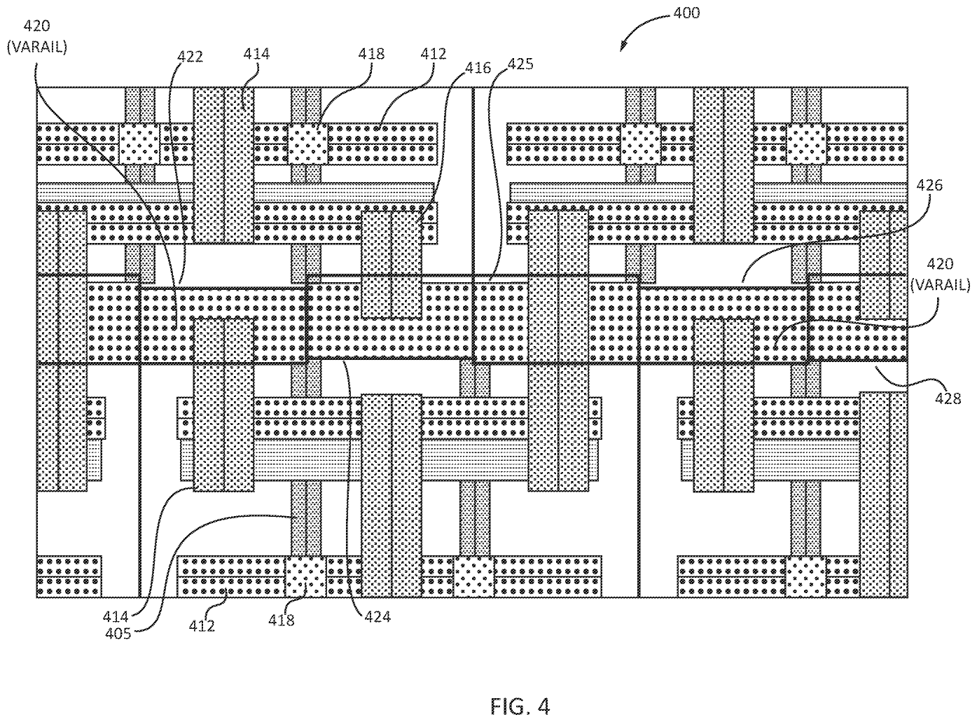

FIG. 4 is a top view of a layout depicting an irregular-shaped power rail with a plurality of notches (and or extensions), in accordance with an embodiment of the present invention.

A top view of a layout 400 depicting an irregular-shaped power rail 420 with a plurality of notches 422, 424, 426, 428 is illustrated. The power rail 420 can extend over a plurality of power CAs 414, 416. Metals lines 412 can run parallel to the power rail 420. The metal lines 412 can be connected by vias 418 to one or more signal CAs 405. The power rail 420 has a non-rectangular shape and the middle-of-line (MOL) contact layer or power CAs 414, 416 electrically connects to the power rail 420 by the metal wiring layer.

The non-rectangular shape can be referred to as a nonlinear shape or irregular-shape or stepped configuration. Irregular-shaped refers to an unbalanced or non-normal or non-conventional or asymmetrical shape and/or arrangement. Irregular-shaped can also refer to uneven or unequal portions or sections.

In an alternative embodiment, the power rail 420 can include one or more extensions 425 or projections further overlapping over the power CAs 414, 416. In yet another alternative embodiment, the power rail 420 can include both notches and extensions at various strategic locations across the length of the power rail 420 to enable both an increase in VARAIL to CA space for signal CAs and to enable an increase in VARAIL to CA overlap for power CAs. Therefore, notches and extensions can be simultaneously or concurrently used to enable a very short cell height to improve area scaling.

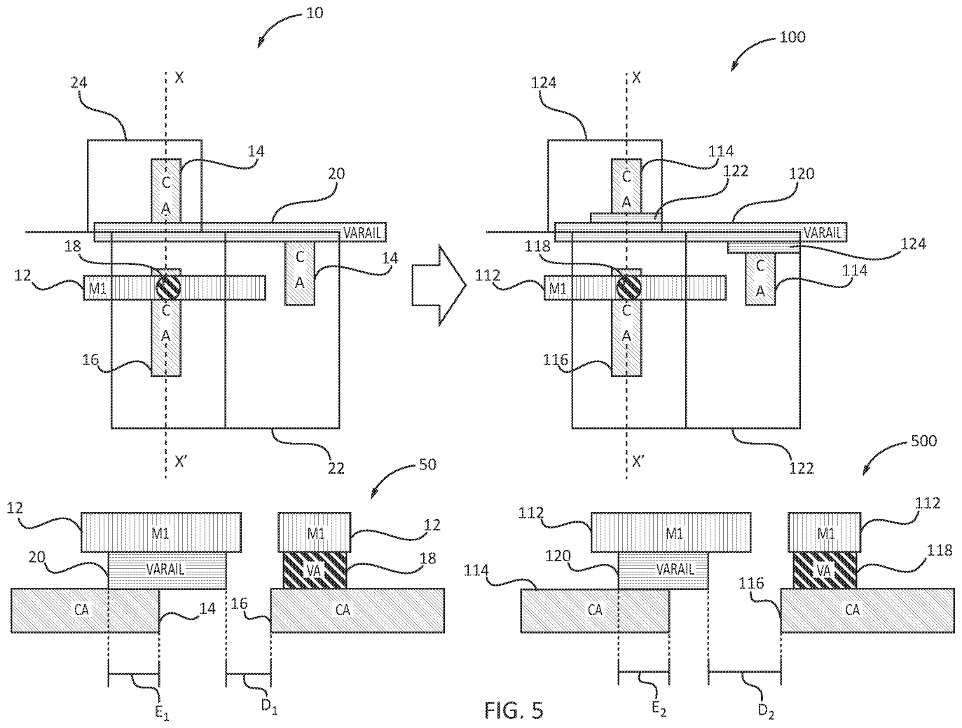

FIG. 5 is a top view of a power rail having a conventional rectangular shape and a power rail having an irregular-shape with extensions, as well as cross-sectional views of the power rails, in accordance with an embodiment of the present invention.

The cross-sectional view 50 along the cut X-X′ of structure 10 illustrates the relationship of the power rail 20 with respect to the metal line 12 and the power CA 14. Additionally, the electrical connection between the metal line 12 and the signal CA 16 by the via 18 is shown. The VARAIL overlap with the power CA is designated as E₁. The VARAIL-to-signal CA space is designated as D₁.

The cross-sectional view 500 along the cut X-X′ of structure 100 illustrates the relationship of the power rail 120 with respect to the metal line 112 and the power CA 114. Additionally, the electrical connection between the metal line 112 and the signal CA 116 by the via 118 is shown. The first projection 122 of the power rail 120 thus enables greater overlap of the power rail 120 over the power CA 114. The VARAIL overlap with the power CA is designated as E₂. The VARAIL-to-signal CA space is designated as D₂. E₂>E₁ and D₂>D₁.

Therefore, in accordance with FIGS. 1-5, a power rail is presented having a non-rectangular shape and a middle-of-line (MOL) contact layer is electrically connected to the power rail by a metal wiring layer. In one embodiment, the non-rectangular shape can include a notch. In another embodiment, the non-rectangular shape can include a plurality of notches. In yet another embodiment, the non-rectangular shape can include an extension. In another embodiment, the non-rectangular shape can include a plurality of extensions. In other exemplary embodiments, the power rail can include both a combination of notches and extensions in accordance with design specifications. Moreover, a portion of the power rail can be wider in a region connecting the power rail to the MOL contact layer. Stated differently, a portion of the power rail can be narrower in a region not connecting the power rail to the MOL contact layer. In other embodiments, a portion of the power rail can be narrower in a region connecting the power rail adjacent the MOL contact layer. Stated differently, a portion of the power rail can be wider in a region connecting the power rail non-adjacent the MOL contact layer.

In conclusion, the exemplary embodiments of the present invention present structures and methods of forming an irregular-shaped power rail in cell power distribution that can increase power rail to power contact (CA) space for the signal CA and increase power rail to CA overlap for a power CA. The irregular-shape of the power rail can be non-linear or can include one or notches or one or more extensions or projections. The notches or projections can be aligned with the signal CA or the power CA, resulting in the enablement of a very short cell height to improve area scaling.

Regarding FIGS. 1-5, deposition is any process that grows, coats, or otherwise transfers a material onto the wafer. Available technologies include, but are not limited to, thermal oxidation, physical vapor deposition (PVD), chemical vapor deposition (CVD), electrochemical deposition (ECD), molecular beam epitaxy (MBE) and more recently, atomic layer deposition (ALD) among others. As used herein, “depositing” can include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The term “processing” as used herein includes deposition of material or photoresist, patterning, exposure, development, etching, cleaning, stripping, implanting, doping, stressing, layering, and/or removal of the material or photoresist as needed in forming a described structure.

Removal is any process that removes material from the wafer: examples include etch processes (either wet or dry), and chemical-mechanical planarization (CMP), etc.

Patterning is the shaping or altering of deposited materials, and is generally referred to as lithography. For example, in conventional lithography, the wafer is coated with a chemical called a photoresist; then, a machine called a stepper focuses, aligns, and moves a mask, exposing select portions of the wafer below to short wavelength light; the exposed regions are washed away by a developer solution. After etching or other processing, the remaining photoresist is removed. Patterning also includes electron-beam lithography and EUV techniques.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which usually include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of methods and structures providing for constructing an irregular-shaped power rail in cell power distribution (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A semiconductor structure comprising:
a power rail having a non-rectangular shape; and
a middle-of-line (MOL) contact layer electrically connected to the power rail by a metal wiring layer.

2. The semiconductor structure of claim 1, wherein the non-rectangular shape includes a notch.

3. The semiconductor structure of claim 1, wherein the non-rectangular shape includes a plurality of notches.

4. The semiconductor structure of claim 1, wherein the non-rectangular shape includes an extension.

5. The semiconductor structure of claim 1, wherein the non-rectangular shape includes a plurality of extensions.

6. The semiconductor structure of claim 1, wherein a portion of the power rail is wider in a region connecting the power rail to the MOL contact layer.

7. The semiconductor structure of claim 1, wherein a portion of the power rail is narrower in a region not connecting the power rail to the MOL contact layer.

8. The semiconductor structure of claim 1, wherein a portion of the power rail is narrower in a region connecting the power rail adjacent the MOL contact layer.

9. The semiconductor structure of claim 1, wherein a portion of the power rail is wider in a region connecting the power rail non-adjacent the MOL contact layer.

10. The semiconductor structure of claim 1, wherein the power rail is a via rail.

11. The semiconductor structure of claim 1, wherein the power rail is a VARAIL.

12. A semiconductor structure comprising:
an irregular-shaped power rail; and
a middle-of-line (MOL) contact layer electrically connected to the irregular-shaped power rail by a metal wiring layer.

13. The semiconductor structure of claim 12, wherein the irregular-shaped power rail includes stepped portions.

14. The semiconductor structure of claim 12, wherein the irregular-shaped power rail includes at least one notch.

15. The semiconductor structure of claim 12, wherein the irregular-shaped power rail includes at least one projection.

16. The semiconductor structure of claim 12, wherein a portion of the irregular-shaped power rail is wider in a region connecting the power rail to the MOL contact layer.

17. The semiconductor structure of claim 12, wherein a portion of the irregular-shaped power rail is narrower in a region not connecting the power rail to the MOL contact layer.

18. The semiconductor structure of claim 12, wherein a portion of the irregular-shaped power rail is narrower in a region connecting the power rail adjacent the MOL contact layer.

19. The semiconductor structure of claim 12, wherein a portion of the irregular-shaped power rail is wider in a region connecting the power rail non-adjacent the MOL contact layer.

20. A method for constructing a semiconductor structure, the method comprising:
forming a power rail having a non-rectangular shape; and
electrically connecting a middle-of-line (MOL) contact layer to the power rail by a metal wiring layer.
